(19) United States
(12) Patent Application Publication
(10) Pub. No.: US 2014/0186654 A1
(43) Pub. Date: Jul. 3, 2014

(54) SURFACE TREATMENT METHOD FOR STAINLESS STEEL AND HOUSING MADE FROM THE TREATED STAINLESS STEEL

(71) Applicants: FIH ( Hong Kong) Limited, Kwoloon (HK); SHENZHEN FUTAIHONG PRECISION INDUSTRY CO. LTD., Shenzhen (CN)

(72) Inventor: CHUN-JIE ZHANG, Shenzhen (CN)

(21) Appl. No.: 13/936,352

(22) Filed: Jul. 8, 2013

(30) Foreign Application Priority Data
Dec. 29, 2012 (CN) 201210589228X

(51) Int. Cl. C23C 14/35; C25D 11/18

(52) U.S. Cl. CPC C23C 14/352; C25D 11/18
USPC 428/656; 205/89

(57) ABSTRACT

A surface treatment method for stainless steel as a colorful and smooth housing includes the steps of: a base layer including titanium is deposited on the stainless steel substrate by multi-arc ion plating. An aluminum transition layer is deposited on the titanium base layer by multi-arc ion plating, and an outermost layer including aluminum is deposited on the transition layer by magnetron sputtering. The transition layer and the outermost layer are anodized to form an anodic aluminum oxide film; and the anodic aluminum oxide film is sealed after being dyed. An article manufactured by the method is also provided.

### BACKGROUND

1. Technical Field

The present disclosure relates to a surface treatment method for stainless steel and housing manufactured with the treated stainless steel.

2. Description of Related Art

Stainless steel has high hardness and high corrosion resistance, therefore it is widely used to form housings of electronic devices. Typically, coatings formed by vacuum deposition can present a metallic but not colorful appearance. Anodizing process can make the housings have colorful decoration layers. However, anodized aluminum housings have low heat output rate and rough surfaces.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure.

Moreover, in the drawings, like reference numerals designate corresponding parts throughout the several views.

FIG. 1 is a flow diagram of an exemplary embodiment of a surface treatment method for stainless steel.

FIG. 2 is a schematic view of an exemplary embodiment of a vacuum coating device.

FIG. 3 is a schematic view of an exemplary embodiment of a stainless steel substrate coated with a base layer, a transition layer, and an outermost layer.

FIG. 4 is a schematic view of an exemplary embodiment of a treated article.

### DETAILED DESCRIPTION

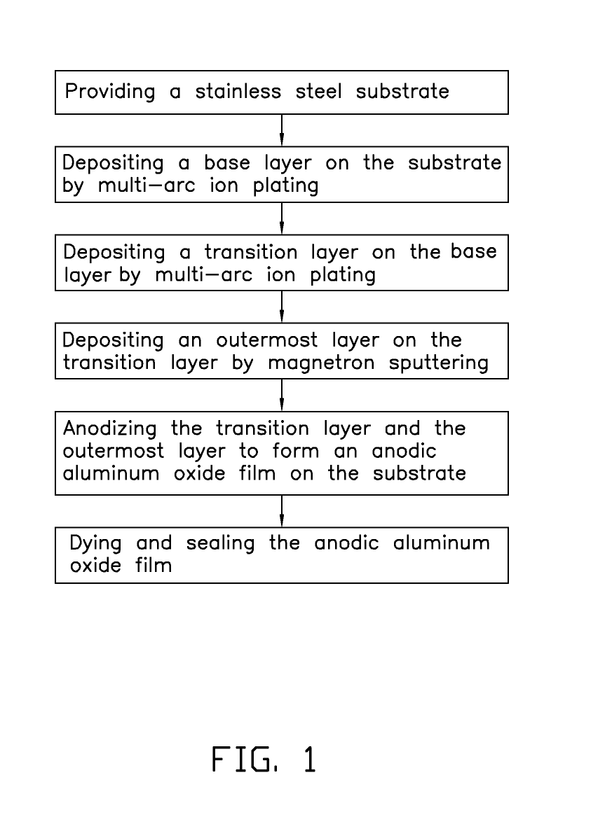

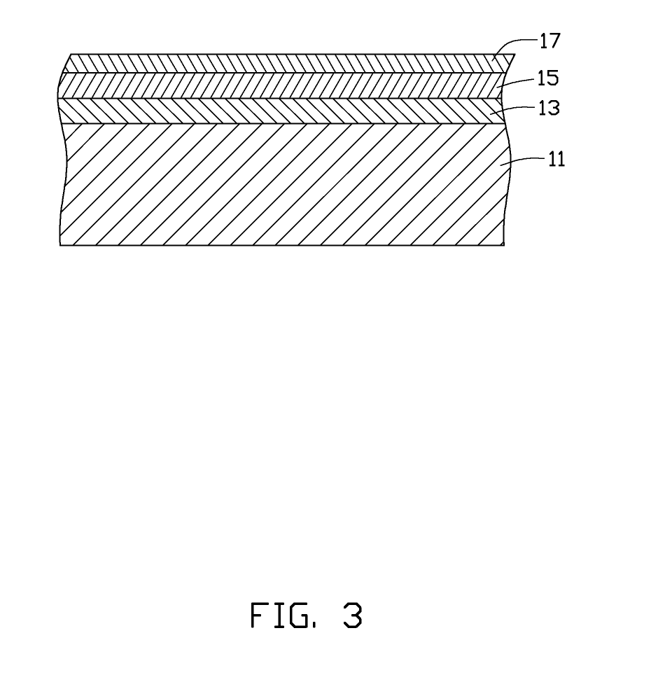

Referring to FIGS. 1 and 3, a surface treatment method for stainless steel according to an exemplary embodiment may include at least the following steps:

A stainless steel substrate 11 is provided.

A base layer 13 is deposited on the substrate 11 by multi-arc ion plating. The base layer 13 comprises titanium. The base layer 13 has a thickness of about 1.5 μm to about 2.5 μm. The method of depositing the base layer 13 may include the following steps:

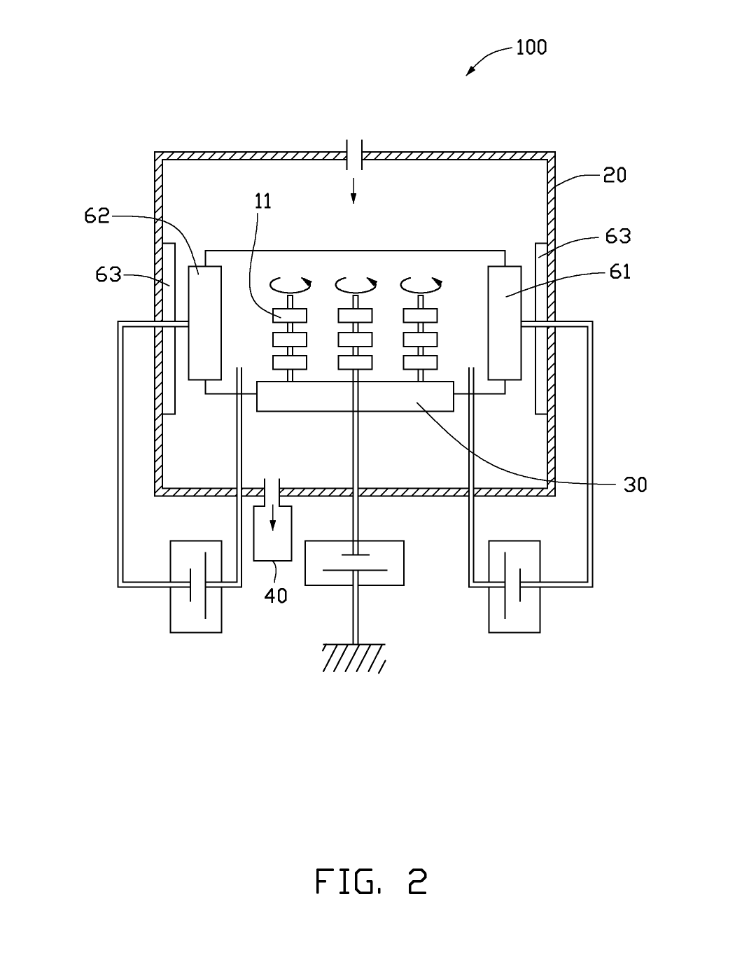

A vacuum coating device 100 is provided as shown in FIG. 2. The vaccum coating device 100 is a multifunctional coating device which can be used for a multi-arc ion plating process or sputtering plating process. The device 100 includes a chamber 20, a rotating bracket 30 mounted within the chamber 20, and a vacuum pump 40 connected to the chamber 20. The vacuum pump 40 is used to evacuate air and gas from the chamber 20. During the depositing of the base layer 13, a plurality of titanium arc targets 61 are mounted within the chamber 20. The substrate 11 is retained on a rotating bracket 30 in the chamber 20.

The chamber 20 is evacuated to about 3×10⁻³ Pa-8.0×10⁻³ Pa. Then, inert gas such as argon is fed into the chamber 20 to adjust the vacuum level inside the chamber 20 to about 0.1 Pa-0.8 Pa. The temperature in the chamber 20 is set between about 90 Celsius degree (° C.) and about 105° C. A bias voltage applied to the substrate 11 may be between about −200 V and about −300 V. The titanium arc targets 61 mounted in the chamber 20 are evaporated under an electric power of about 15 V-30 V and an electric current of about 50 A-80 A. The electric power may be a medium-frequency AC power, with a duty cycle of about 40% to about 50%. Depositing of the base layer 13 takes about 10 min-25 min.

A transition layer 15 is deposited on the base layer 13 by multi-arc ion plating. The transition layer 15 comprises aluminum. The transition layer 15 has a thickness of about 13 μm-22 μm. The method of depositing the transition layer 15 may include the following steps:

A plurality of aluminum arc targets 62 are mounted within the chamber 20. The chamber 20 is evacuated to about 3×10⁻³ Pa-8.0×10⁻³ Pa. Inert gas such as argon is fed into the chamber 20 to adjust the vacuum level inside the chamber 20 to about 0.1 Pa-0.9 Pa. The temperature in the chamber 20 is set between about 90° C. and about 115° C. A bias voltage applied to the substrate 11 may be about −200 V. The aluminum arc targets 62 in the chamber 20 are evaporated under an electric power of about 15 V-35 V and an electric current of about 40 A-70 A, for about 25 min-60 min. The electric power may be a medium-frequency AC power, with a duty cycle of about 45%. Depositing of the transition layer 15 takes about 25 min-60 min.

An outermost layer 17 is deposited on the transition layer 15 by magnetron sputtering. The outermost layer comprises aluminum. The outermost layer 17 has a thickness of about 3 μm-5 μm. The method of depositing the outermost layer 17 may include the following steps:

A plurality of aluminum sputtering targets 63 are mounted within the chamber 20. The substrate 11 being coated with the base layer 13 and the transition layer 15 is retained on the rotating bracket 30 in the chamber 20. The chamber 20 is evacuated to about 3×10⁻³ Pa-8.0×10⁻³ Pa. Inert gas such as argon is fed into the chamber 20 to adjust the vacuum level inside the chamber 20 to about 0.1 Pa-0.9 Pa. The temperature in the chamber 20 is set between about 120° C. and about 130° C. A bias voltage applied to the substrate 11 may be about −200 V. The aluminum sputtering targets 63 in the chamber 20 are evaporated under an electric power of about 5 kW-6 kW. The electric power may be a medium-frequency AC power, with a duty cycle of about 40%. Depositing of the transition layer 15 takes about 50 min-70 min.

The transition layer 15 and the outermost layer 17 are anodized to form an anodic aluminum oxide film 19 on the base layer 13. The anodizing process may be carried out in an aqueous anodizing electrolyte for about 10 min to about 15 min. The electrolyte contains sulfuric acid having a mass concentration of about 190 g/L-210 g/L. The electrolyte has a temperature of about 8° C. to about 13° C. during the anodizing process. The anodizing voltage is about 13 V.

The anodic aluminum oxide film 19 can be sealed after dyeing. The sealing process is carried out in a hot water having a temperature of about 95° C.-98° C. for about 10 min-20 min.

During depositing of the base layer 13, the transition layer 15, and the outermost layer 17, the duty cycle of the electric power applied to the targets is gradually decreased. The depositing rate also gradually decreases with the decreasing of the duty cycle. As such, the strength and integrity of the bonds between the base layer 13, the transition layer 15, and the outermost layer 17 are enhanced.

The anodic aluminum oxide film 19 can be dyed to a desired color. The base layer 13 prevents the substrate 11 from being eroded during the anodizing process. The base layer 13 formed by multi-arc ion plating is tightly bonded with the substrate 11. The transition layer 15 improves the bonding between the base layer 13 and the outermost layer 17. The outermost layer 17 formed by sputtering plating has a smooth surface, thus the anodic aluminum oxide film 19 also has a smooth surface.

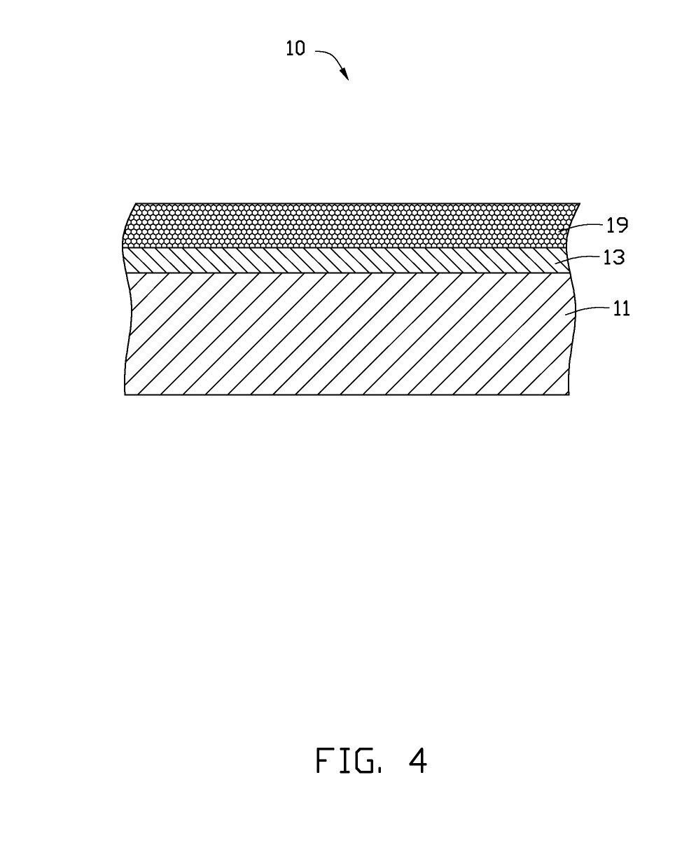

Referring to FIG. 4, an article 10 manufactured by the above method is also provided. The article 10 includes a stainless steel substrate 11, a base layer 13 formed on the substrate 11, and an anodic aluminum oxide film 19 formed on the base layer 11. The base layer 13 comprises of titanium. The base layer 13 has a thickness of about 1.5 μm-2.5 μm. The anodic aluminum oxide film 19 has a thickness of about 18 μm-25 μm.

### EXAMPLE 1

A base layer 13 was deposited on the substrate 11 by multi-arc ion plating. Eight titanium arc targets 61 were mounted within the chamber 20. The substrate 11 was retained on the rotating bracket 30 in the chamber 20. The chamber 20 was evacuated to about 5.0×10⁻³ Pa. Argon was fed into the chamber 20 at a flow rate of about 100 sccm to adjust the vacuum level inside the chamber 20 to about 0.2 Pa. The temperature in the chamber 20 was set to about 95° C. A bias voltage of about −300 V was applied to the substrate 11. The titanium targets 61 in the chamber 20 were evaporated under an electric power of about 30 V and an electric current of about 75 A. The duty cycle of the electric power was about 50%. Depositing of the base layer 13 took about 10 min. The base layer 13 was a titanium layer having a thickness of about 2 μm.

A transition layer 15 was deposited on the base layer 13 by multi-arc ion plating. The substrate 11 was retained on the rotating bracket 30 in the chamber 20. Argon was fed into the chamber 20 at a flow rate of about 200 sccm, to keep the vacuum level inside the chamber 20 at about 0.2 Pa. The temperature in the chamber 20 was set to about 95° C. A bias voltage of about −200 V was applied to the substrate 11. The aluminum arc targets 62 in the chamber 20 were evaporated under an electric power of about 25 V and an electric current of about 70 A. The duty cycle of the electric power was about 45%. Depositing of the transition layer 15 took about 60 min. The transition layer 15 was an aluminum layer having a thickness of about 13 μm.

An outermost layer 17 was deposited on the transition layer 15 by magnetron sputtering. Argon was fed into the chamber 20 at a flow rate of about 250 sccm, to keep the vacuum level inside the chamber 20 at about 0.23 Pa. The temperature in the chamber 20 was set to about 120° C. A bias voltage of about −250 V was applied to the substrate 11. The aluminum sputtering targets 63 in the chamber 20 were evaporated under an electric power of about 5 kW. The duty cycle of the electric power was about 40%. Depositing of the outermost layer 17 took about 70 min. The outermost layer 17 was an aluminum layer having a thickness of about 5 μm.

The transition layer 15 and the outermost layer 17 were anodized to form the anodic aluminum oxide film 19 on the base layer 13. The electrolyte contained sulfuric acid having a mass concentration of about 195 g/L. The anodizing electrolyte had a temperature of about 12° C. during the anodizing process. The anodizing voltage was about 13 V. The anodizing process lasted about 18 min.

The anodic aluminum oxide film 19 was dyed and sealed.

### EXAMPLE 2

A base layer 13 was deposited on the substrate 11 by multi-arc ion plating. The substrate 11 was retained on the rotating bracket 30 in the chamber 20. The chamber 20 was evacuated to about 5.0×10⁻³ Pa. Argon was fed into the chamber 20 at a flow rate of about 80 sccm, to adjust the vacuum level inside the chamber 20 to about 0.15 Pa. The temperature in the chamber 20 was set about 105° C. A bias voltage of about −300 V was applied to the substrate 11. The titanium arc targets 61 in the chamber 20 were evaporated under an electric power of about 20 V and an electric current of about 70 A. The duty cycle of the electric power was about 50%. Depositing of the base layer 13 took about 10 min. The base layer 13 was a titanium layer having a thickness of about 1.5 μm.

A transition layer 15 was deposited on the base layer 13 by multi-arc ion plating. The substrate 11 was retained on the rotating bracket 30 in the chamber 20. Argon was fed into the chamber 20 at a flow rate of about 80 sccm, to keep the vacuum level inside the chamber 20 at about 0.15 Pa. The temperature in the chamber 20 was set about 105° C. A bias voltage of about −200 V was applied to the substrate 11. The aluminum arc targets 62 in the chamber 20 were evaporated under an electric power of about 20 V and an electric current about 70 A. Depositing of the transition layer 15 took about 60 min. The duty cycle of the electric power was about 45%. The transition layer 15 was an aluminum layer having a thickness of about 13 μm.

An outermost layer 17 was deposited on the transition layer 15 by magnetron sputtering. Argon was fed into the chamber 20 at a flow rate of about 250 sccm, to keep the vacuum level inside the chamber 20 at about 0.17 Pa. The temperature in the chamber 20 was set to about 130° C. A bias voltage of about −250 V was applied to the substrate 11. The aluminum sputtering targets 63 in the chamber 20 were evaporated under an electric power of about 6 kW. The duty cycle of the electric power was about 40%. Depositing of the outermost layer 17 took about 50 min. The outermost layer 17 was an aluminum layer having a thickness of about 4 μm.

The transition layer 15 and the outermost layer 17 were anodized to form the anodic aluminum oxide film 19. The electrolyte contained sulfuric acid having a mass concentration of about 210 g/L. The anodizing electrolyte had at a temperature of about 13° C. during the anodizing process. The anodizing voltage was about 12 V. The anodizing process lasted about 18 min.

The anodic aluminum oxide film 19 was dyed and sealed.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A surface treatment method for stainless steel comprising:
providing a stainless steel substrate;
depositing a base layer on the stainless steel substrate by multi-arc ion plating, the base layer comprising titanium;
depositing a transition layer on the base layer by multi-arc ion plating, the transition layer comprising aluminum;
depositing an outermost layer on the transition layer by magnetron sputtering, the outermost layer comprising aluminum;
anodizing the transition layer and the outermost layer to form an anodic aluminum oxide film on the base layer; and
dyeing and sealing the anodic aluminum oxide film.

2. The method of claim 1, wherein the base layer, the transition layer, and the outermost layer are formed in a vacuum coating device, the vacuum coating device comprising a chamber, a rotating bracket mounted within the chamber, and a vacuum pump connected to the chamber.

3. The method of claim 2, wherein during depositing the base layer, a plurality of titanium arc targets are mounted within the chamber, argon is fed into the chamber to adjust the vacuum level inside the chamber to about 0.1 Pa-0.8 Pa, the temperature in the chamber is set between about 90° C. and about 105° C., a bias voltage applied to the stainless steel substrate is between about −200 V and about −300 V, the titanium arc targets in the chamber are evaporated under an electric power of about 15 V-30 V and an electric current of about 50 A-80 A, the duty cycle of the electric power is about 40% to about 50%, depositing of the base layer takes about 10 min-25 min.

4. The method of claim 2, wherein during depositing the transition layer, a plurality of aluminum arc targets are mounted within the chamber, argon is fed into the chamber to adjust the vacuum level inside the chamber to about 0.1 Pa-0.9 Pa, the temperature in the chamber is set between about 90° C. and about 115° C., a bias voltage applied to the stainless steel substrate is about −200 V, the aluminum arc targets are evaporated under an electric power of about 15 V-35 V and an electric current about 40 A-70 A, the duty cycle of the electric power is about 45%, depositing of the transition layer takes about 25 min-60 min.

5. The method of claim 3, wherein during depositing the outermost layer, a plurality of aluminum sputtering targets are mounted within the chamber, the chamber is evacuated to about 3×10⁻³ Pa-8.0×10⁻³ Pa, argon is fed into the chamber to adjust the vacuum level inside the chamber to about 0.1 Pa-0.9 Pa, the temperature in the chamber is set between about 120° C. and about 130° C., a bias voltage applied to the stainless steel substrate 11 is about −200 V, the aluminum sputtering targets are evaporated under an electric power of about 5 kW-6 kW, the duty cycle of the electric power is about 40%, depositing of the outermost layer takes about 50 min-70 min.

6. The method of claim 1, wherein the anodizing process is carried out in an aqueous anodizing electrolyte for about 10 min to about 15 min, the electrolyte contains sulfuric acid has a mass concentration of about 190 g/L-210 g/L, the anodizing electrolyte is maintained at a temperature of about 8° C. to about 13° C., the anodizing voltage is about 13 V.

7. The method of claim 1, wherein the sealing process is carried out in hot water with a temperature of about 95° C.-98° C. for about 10 min-20 min.

8. An article comprising:
a stainless steel substrate;
a base layer formed on the stainless steel substrate, the base layer comprising titanium; and
an anodic aluminum oxide film formed on the base layer.

9. The article of claim 8, wherein the base layer has a thickness of about 1.5 μm-2.5 μm.

10. The article of claim 8, wherein the anodic aluminum oxide film has a thickness of about 18 μm-25 μm.
